(19) United States
(12) Patent Application Publication
(10) Pub. No.: US 2025/0258024 A1
(43) Pub. Date: Aug. 14, 2025

(54) METHOD AND APPARATUS FOR DETECTING PESTS USING LOW POWER CAPACITIVE SENSING

(71) Applicants: Daniel Ronald Schwartz, Cottage Grove, MN (US); Larry Arvid Lake, Woodbury, MN (US); Alissa Ellingson, Woodbury, MN (US); Husam Ismail, Rosemount, MN (US); Kyle David Wood, Rosemount, MN (US)

(72) Inventors: Daniel Ronald Schwartz, Cottage Grove, MN (US); Larry Arvid Lake, Woodbury, MN (US); Alissa Ellingson, Woodbury, MN (US); Husam Ismail, Rosemount, MN (US); Kyle David Wood, Rosemount, MN (US)

(21) Appl. No.: 19/052,585

(22) Filed: Feb. 13, 2025

Related U.S. Application Data
(60) Provisional application No. 63/552,881, filed on Feb. 13, 2024.

(51) Int. Cl. G01D 18/00; A01M 31/00; G01D 5/24

(52) U.S. Cl. CPC G01D 18/006; A01M 31/002; G01D 5/2405

(57) ABSTRACT

Various examples are directed to apparatus and methods for enhanced pest detection and enhanced battery life for a power supply of a pest detection device. The pest detection device includes a capacitive sensor configured to detect a presence of one or more pests, and one or more secondary sensors configured to detect one or more prescribed conditions. The pest detection device also includes a controller connected to the capacitive sensor and the one or more secondary sensors. The controller is configured to initiate calibration of the capacitive sensor based at least in part on one or more signals received from the one or more secondary sensors.

### CROSS-REFERENCE TO RELATED APPLICATION

This patent application claims the benefit of U.S. Provisional Patent Application No. 63/552,881, filed Feb. 13, 2024, which is incorporated by reference herein in its entirety.

### TECHNICAL FIELD

The present disclosure pertains to methods and apparatus for pest detection devices, and more particularly to methods and apparatus for a pest detection device with improved capacitive sensing.

### BACKGROUND

A number of devices are used to detect pests. One such device is an electronic sensor that detects the presence of a pest by measuring a change in capacitance due to a pest's presence on a capacitive sensor.

Capacitive sensing can be used to detect, among other things, the presence of an object or body within relation to the sensor itself. For example, capacitive sensing is used for touch screens and touchpads (e.g., to detect the presence of a finger) where human interfaces are needed to make inputs such as with cell phones, computers, automotive displays, and many other applications. The large capacitive potential of the human body makes these applications essentially static, such that the capacitive sensor does not require recalibration once set, as the large shift in capacitance is easily measured and has a wide band of tolerance to filter out false activations (e.g., water on the sensor). This is not the case with pests, however, which can be extremely small in both size and weight.

Capacitive sensors for pest detection must be able to detect not only adult insects but also the nymphs, which are extremely small in comparison. In order for changes in the environment to not cause errors in the capacitive sensing accuracy for pest detection, the on-going recalibration of the capacitive sensor to automatically adjust to changing conditions is vital. Typically, this recalibration is done as a continuous or near-continuous process to ensure the sensor is updated, however this requires power and has a negative impact on battery life.

Another problem with present sensors is that smaller pests may be difficult to detect based on the sensor design. For example, a sensor that is configured for a certain insect of a certain size may not detect smaller insects, therefore also rendering inaccurate sensing results.

There is a need in the art for an improved pest detection device that will have longer battery life and better detect pests.

### SUMMARY

A system for pest detection device with improved capacitive sensing and improved battery life is provided. The present apparatus and methods provide a pest detection device with an additional sensor or sensors that provide feedback to a controller for initiation of capacitive sensor calibration, ensuring accurate pest detection and providing improved battery life compared to current devices that rely on near-continuous calibration of capacitive sensors. In various embodiments, the pest detection device includes one or more additional or secondary sensors that monitor one or more prescribed conditions such as environmental factors to trigger capacitive sensor calibration. The secondary sensor or sensors may be deployed internally or externally to the pest detection device, and may work individually or in a coordinated manner to improve functioning of the device.

Various examples are directed to apparatus and methods for enhanced pest detection and enhanced battery life for a power supply of a pest detection device. The pest detection device includes a capacitive sensor configured to detect a presence of one or more pests, and one or more secondary sensors configured to detect one or more prescribed conditions. The pest detection device also includes a controller connected to the capacitive sensor and the one or more secondary sensors. The controller is configured to initiate calibration of the capacitive sensor based at least in part on one or more signals received from the one or more secondary sensors.

Various examples are directed to a method for detecting pests using low power capacitive sensing. The method includes using a capacitive sensor to detect a presence of one or more pests and using one or more secondary sensors to detect one or more prescribed conditions. The method further includes using a controller connected to the capacitive sensor and the one or more secondary sensors to initiate calibration of the capacitive sensor based at least in part on one or more signals received from the one or more secondary sensors.

This Summary is an overview of some of the teachings of the present application and not intended to be an exclusive or exhaustive treatment of the present subject matter. Further details about the present subject matter are found in the detailed description and appended claims. The scope of the present invention is defined by the appended claims and their legal equivalents.

### BRIEF DESCRIPTION OF THE DRAWINGS

The drawings illustrate generally, by way of example, various embodiments discussed in the present document. The drawings are for illustrative purposes only and may not be to scale.

FIG. 1A is an illustration of an embodiment of a pest detection device showing components of the device.

FIG. 1B is an illustration of an embodiment of a pest detection device showing external components of the device.

FIG. 1C is an illustration of a top down cross-section of a pest containment device, according to various embodiments.

FIG. 2 illustrates an example embodiment of a method for detecting pests using low power capacitive sensing, according to various embodiments.

FIG. 3 is a block diagram of a machine in the example form of a computer system within which a set of instructions may be executed, for causing the machine to perform any one or more of the methodologies discussed herein.

### DETAILED DESCRIPTION

The following detailed description of the present subject matter refers to subject matter in the accompanying drawings which show, by way of illustration, specific aspects and embodiments in which the present subject matter may be practiced. These embodiments are described in sufficient detail to enable those skilled in the art to practice the present subject matter. References to “an”, “one”, or “various” embodiments in this disclosure are not necessarily to the same embodiment, and such references contemplate more than one embodiment. The scope of the present invention is defined by the appended claims, along with the full scope of legal equivalents to which such claims are entitled.

Pest detection devices relying on capacitive sensors for small pest detection typically use frequent or continuous calibration and recalibration of the capacitive sensors to ensure sufficient sensitivity. In the past, these devices were often hard-wired or plug-in power supplies to enable the frequent recalibration. The present system provides for a more limited recalibration rate to enable battery-operated pest detection devices to provide long-lasting and accurate detection of even the smallest of insects or other pests.

This application incorporates by reference the entirety of U.S. Pat. No. 6,937,156, titled: Method and Apparatus for Capacitively Sensing Pests, which is owned by applicant Ecolab, Inc.

Capacitive sensing uses a change in electrical state from a known baseline value (or calibration) to a new level when an object or body comes within range of the sensor. Changes in the environment around a pest detection device with a capacitive sensor may change the baseline value for the capacitive sensor, requiring a recalibration of the capacitive sensor to ensure that a state change can be sensed. The need for recalibration is even more important when a capacitive sensor is used for sensing smaller objects, such as bugs or other small pests. In this situation, this recalibration is typically done as a continuous or near-continuous process to ensure the capacitive sensor is updated and functioning properly. However, this frequent recalibration requires electrical power and has a negative impact on battery life. The present subject matter provides an apparatus and method of using one or more secondary sensors to detect a change in a prescribed condition (such as the environment around the device) that may cause the need to recalibrate. By only recalibrating when indicated such as by a sensor signal, the present subject matter provides improved sensing and significant electrical power savings, which is critical for enabling a battery-powered version of the pest detection device.

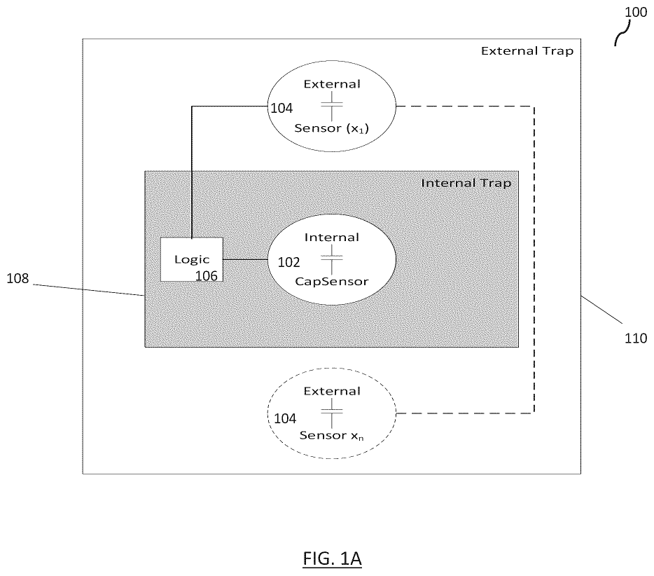

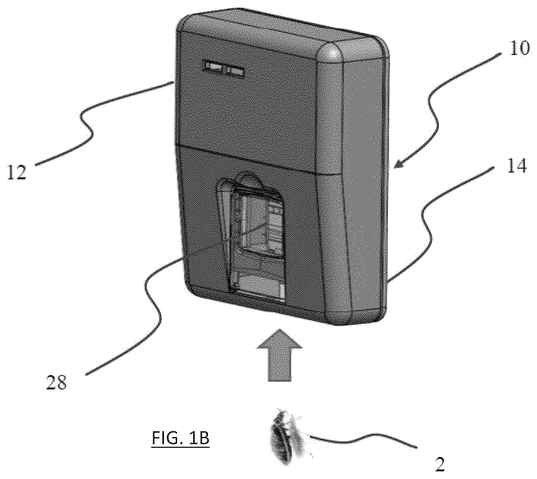

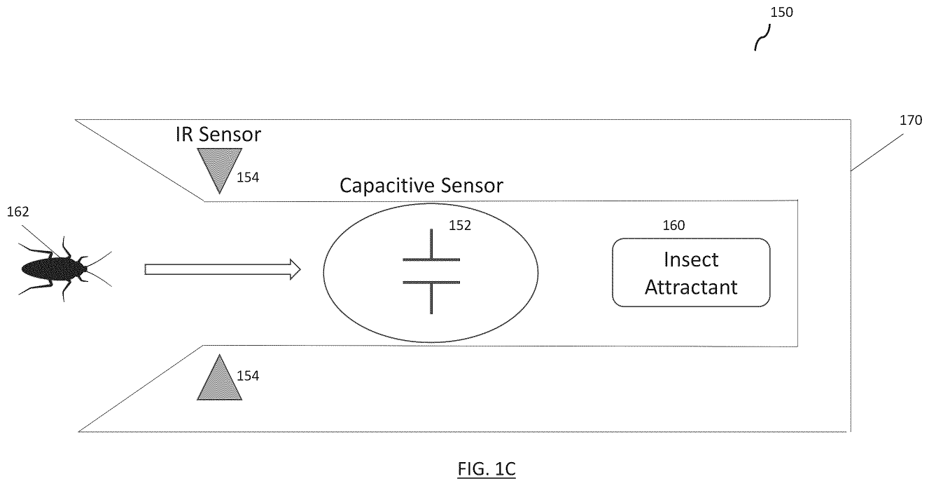

FIG. 1A is a schematic drawing of a pest detection device 100 (or pest monitoring device, or pest containment device such as a trap), according to one embodiment of the present subject matter. The pest detection device 100 includes a capacitive sensor 102 (or internal sensor) configured to detect a presence of one or more pests, and one or more secondary sensors 104 (or additional sensors or external sensors) configured to detect one or more prescribed conditions. The pest detection device 100 also includes a controller 106 (or logic or circuit) connected to the capacitive sensor 102 and the one or more secondary sensors 104. The controller 106 is configured to control calibration of the capacitive sensor 102 based at least in part on one or more signals received from the one or more secondary sensors 104. The present subject matter thus provides for enhanced pest detection and enhanced battery life for a power supply of the pest detection device 100. The capacitive pest detection of the present subject matter may be used for monitoring, detecting, or trapping insects (such as cockroaches or bedbugs), rodents (such as mice or rats), or other types of pests including, but not limited to, those discussed in this document.

In various embodiments, the controller 106 and capacitive sensor 102 are disposed in an internal portion 108 of the pest detection device 100. In the depicted embodiment, the secondary sensors 104 are configured to sense events or conditions external to the pest detection device 100. In some embodiments, the secondary sensors 104 are disposed on an external portion 110 of the pest detection device 100. However, the present subject matter is not so limited, and the secondary sensors 104 may be configured to sense events or conditions external to the pest detection device 100 by placement that is at least partially within the internal portion 108 of the device 100, or at least partially external to the device 100, on an internal surface of device 100, on an external surface of device 100, or in another location, in various embodiments.

The one or more secondary sensors 104 may include combinations of one or more of: a mechanical sensor, a mechanical switch, a capacitive sensor, a MEMS sensor, a Hall effect sensor, an inductance sensor, a conductance sensor, an impedance sensor, an infrared sensor, an optical sensor, a vibration sensor, an acoustic sensor, an environmental sensor (such as a temperature, humidity or moisture detector), and other types of sensors. Other types and combinations of sensors may be used for the one or more secondary sensors 104 without departing from the scope of the present subject matter. The sensors may include a watchdog timer and/or additional processing circuitry, in various examples.

In various examples, the one or more secondary sensors 104 may include a plurality of secondary sensors, and the plurality of secondary sensors may be of a same sensor type or may include multiple sensor types. According to various examples, the pest detection device may include a battery configured to be used for calibration of the capacitive sensor, and/or to power the device. Battery power can be advantageous in certain situations for pest detection, as some internal environments (such as commercial kitchens) have a limited number of power outlets, and some external environments may be completely devoid of such outlets. Battery power also increases the placement options for devices about a location. Additionally, battery powered devices allow for systems which may include charging sources, such as solar power charging sources, wireless or inductive power charging sources, thermal power (e.g., thermopile) charging sources, mechanical power (e.g., wind power devices) charging sources, and/or other charging sources.

The controller is configured to detect capacitance changes using the capacitive sensor, and may include a microprocessor, a microcontroller, a circuit, logic components, or combinations thereof to perform the detection and other functions for the device, in various embodiments. The device 100 may also include wireless communication capability including, but not limited to, a long and/or short range wireless antenna and associated communication circuitry. A number of wireless protocols may be used by the present device to communicate and report pest detection results or other data to one or more external devices (such as a computer, a smartphone, a tablet, etc.), to other pest detection devices, to a router, to a gateway, or the like. The wireless standards that may be used by the present subject matter include, but are not limited to, one or more of the following: LoRa, near-field communication (NFC), Bluetooth, Bluetooth Low Energy (BLE), Ethernet, Wi-Fi, WiMax, Zigby, or cellular standard communications such as 3G, 4G, LTE, 5G. Other wireless standards may be used without departing from the scope of the present subject matter.

In various embodiments, the capacitive sensor 102 is included in the internal portion 108 of the detection device 100 and is calibrated soon after powering up the device. The sensor may be configured to sense without recalibration (in other words, remain static) unless there is a sense event by one or more secondary sensors 104 which indicate the potential need to perform another capacitive sensor calibration. The secondary sensors 104 may include an input trigger such as a mechanical switch or infrared (IR) beam being tripped, an environmental sensor such as a temperature and/or humidity sensor, a watchdog timer, or any other sensor, and can be used alone or in combination with any of the other secondary sensors to indicate that the capacitive sensor 102 may be recalibrated, in various embodiments. The secondary sensors 104 may sense one or more of a change in environmental condition, a presence of a pest, a manual input, a battery level, or any other prescribed condition. The controller 106 may receive a signal from the one or more secondary sensors 104 and control recalibration of the capacitive sensor 102.

In various embodiments, the controller 106 may increment a counter to use for recalibration control, thereby performing recalibration if a certain predetermined count is detected. In various embodiments, the various secondary sensors 104 may be accorded the same count per detection. In various embodiments, the various secondary sensors 104 may be accorded different count values per detection. In various embodiments, a secondary sensing event may automatically initiate recalibration of the capacitive sensor 102. In various embodiments, the controller 106 may receive a signal from the one or more secondary sensors 104 and compare the signal (or data communicated using the signal or signals) to a threshold, and if the threshold is exceeded, proceed to initiate recalibration of the capacitive sensor 102.

In various embodiments, the controller 106 may include a timer that indicates a recalibration event should be performed. In various embodiments, the timer may be used as a watchdog timer so as to provide a recalibration within a predetermined time range to ensure that the capacitive sensor 102 is recalibrated occasionally so as to ensure sensing is accurate. In various embodiments, that timer may reset each time another calibration event is sensed by any or certain of the other sensors of the system, so as to reduce the number of unnecessary recalibrations. Other uses of the signal or signals by the controller 106 to initiate the recalibration may be adapted without departing from the scope of the present subject matter. For example, in systems where the battery state is known, the controller may adjust the conditions and/or rate of recalibration depending on the state of the power source. As another example, in systems allowing for recharging of the power source of the device 100, such systems may adjust the rate of recalibration as a function of the system's ability to recharge itself or as a function of the level of charge. Those of skill in the art will appreciate that other approaches are possible without departing from the scope of the present subject matter.

FIG. 1B is a perspective drawing of a pest detection device 10, according to one embodiment of the present subject matter. The pest detection device 10 includes circuitry within a housing 12 to perform various sensing functions. In various embodiments, the device 10 detects when a pest 2 has entered a sensor area 28. In various applications it is mounted so that pests, such as insects, enter into a sensor area 28 for detection. The sensor area 28 may include one or more capacitive sensors. In various examples, one or more secondary sensors (not shown) may be included internally or externally to the housing, and configured to send a signal to a controller to be used to initiate recalibration of the one or more capacitive sensors. The housing 12 may include a back side 14 with an adhesive or other mounting apparatus to more easily attach the pest detection device 10 to a surface. In portable variations of the present pest detection device, the device will include one or more batteries (not shown) to operate without the need for conventional AC voltage from a wall outlet. In various embodiments, power may be provided by a plug for use with a conventional wall outlet. The device 10 may further include a display element such as a light emitting diode (LED) on a surface of the housing 12, or other type of display for providing device status or the like.

FIG. 1C is an illustration of a top down cross-section of a pest containment device, according to various embodiments. The depicted embodiment shows an insect containment device 150, but other types of detection or containment devices may be used without departing from the scope of the present subject matter. The insect containment device 150 includes a housing 170 and an insect attractant 160 within the housing to attract insects 162. The insect containment device further includes a capacitive sensor 152 within the housing. The capacitive sensor 152 may be used to sense the presence of an insect, to provide a rough size of the insect, and/or to identify the insect based on body type, walking characteristics, or other identifying traits which may be stored in a predetermined profile, for example.

The insect containment device may further include one or more secondary sensors 154. In the depicted embodiment, the secondary sensors 154 are infrared sensors. In various examples, the secondary sensors 154 may be included internally or externally to the housing 170. The secondary sensors 154 may be used to detect pests or insects, provide a count of the pests or insects, and/or to provide a signal to calibrate the capacitive sensor 152. The secondary sensors 154 may sense one or more of a change in environmental condition, a presence of a pest, a manual input, a battery level, or any other prescribed condition. A controller (not shown), either as part of the device 150 or remote from the device 150, may receive a signal from the one or more secondary sensors 154 and control recalibration of the capacitive sensor 152 based on the signal, in various embodiments. In one embodiment, the secondary sensors 154 sense the presence of an insect 162, and send a signal to trigger calibration of the capacitive sensor 152 based on the presence of the insect 162. In some embodiments, the secondary sensors 154 may create a signature of the insect 162, such as an infrared signature, and the signature may be used to corroborate the presence of the insect 162 using other sensors, such as the capacitive sensor 152.

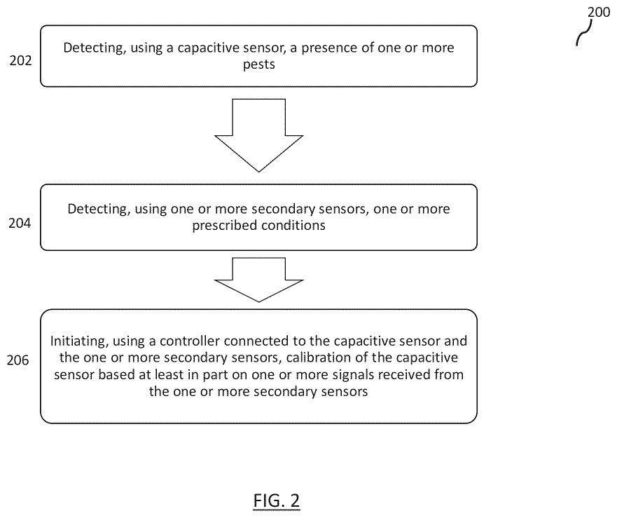

FIG. 2 illustrates an example embodiment of a method 200 for detecting pests using low power capacitive sensing, according to various embodiments. The method 200 includes using a capacitive sensor to detect a presence of one or more pests, at step 202, and using one or more secondary sensors to detect one or more prescribed conditions, at step 204. At step 206, the method 200 further includes using a controller connected to the capacitive sensor and the one or more secondary sensors to initiate calibration of the capacitive sensor based at least in part on one or more signals received from the one or more secondary sensors.

In various embodiments, a method for making the sensing device 100 includes disposing a capacitive sensor and a controller in a housing for a pest detection device. In some embodiments, the method further includes disposing at least one of the one or more secondary sensors about the housing configured to sense one or more events or conditions outside the housing. In various embodiments, the method includes disposing at least one of the one or more secondary sensors external to the housing, disposing at least one of the one or more secondary sensors internal to the housing, and/or disposing at least one of the one or more secondary sensors at least partially external to the housing, disposing at least one of the one or more secondary sensors at least partially internal to the housing. In various embodiments, the capacitive sensor includes a plurality of independent capacitive sensors.

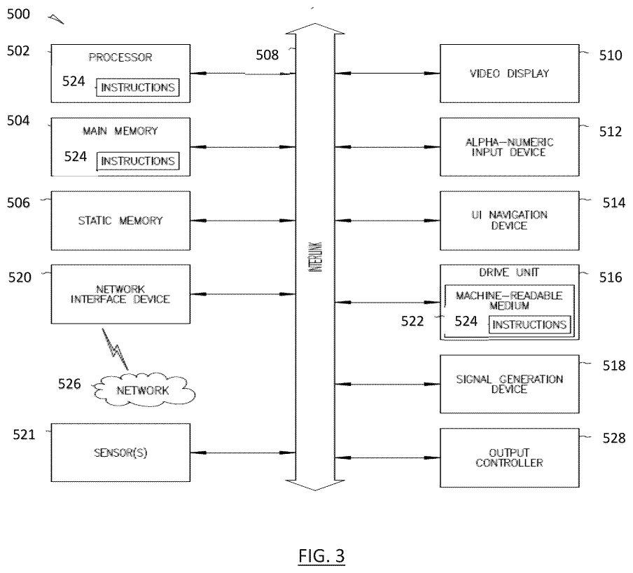

FIG. 3 illustrates a block diagram of an example machine 500 upon which any one or more of the techniques (e.g., methodologies) discussed herein may perform. In alternative embodiments, the machine 500 may operate as a standalone device or may be connected (e.g., networked) to other machines. In a networked deployment, the machine 500 may operate in the capacity of a server machine, a client machine, or both in server-client network environments. In an example, the machine 500 may act as a peer machine in peer-to-peer (P2P) (or other distributed) network environment. The machine 500 may be configured to perform the method of FIG. 2. The machine 500 may be in the form of a personal computer (PC), a tablet PC, a set-top box (STB), a personal digital assistant (PDA), a mobile telephone, a smart phone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate on, logic or a number of components, modules, or mechanisms. Modules are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

Machine (e.g., computer system) 500 may include a hardware processor 502 (e.g., a central processing unit (CPU), a graphics processing unit (GPU), a hardware processor core, or any combination thereof), a controller, a microcontroller, a microprocessor, a main memory 504 and a static memory 506, some or all of which may communicate with each other via an interlink (e.g., bus) 508. The machine 500 may further include a display unit 510, an alphanumeric input device 512 (e.g., a keyboard), and a user interface (UI) navigation device 514 (e.g., a mouse). In an example, the display unit 510, input device 512 and UI navigation device 514 may be a touch screen display. The machine 500 may additionally include a storage device (e.g., drive unit) 516, a signal generation device 518 (e.g., a speaker), a network interface device 520, and one or more sensors 521, such as a global positioning system (GPS) sensor, compass, accelerometer, or other sensor. The machine 500 may include an output controller 528, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 516 may include a machine readable medium 522 on which is stored one or more sets of data structures or instructions 524 (e.g., software) embodying or utilized by any one or more of the techniques or functions described herein. The instructions 524 may also reside, completely or at least partially, within the main memory 504, within static memory 506, or within the hardware processor 502 during execution thereof by the machine 500. In an example, one or any combination of the hardware processor 502, the main memory 504, the static memory 506, or the storage device 516 may constitute machine readable media.

While the machine readable medium 522 is illustrated as a single medium, the term “machine readable medium” may include a single medium or multiple media (e.g., a centralized or distributed database, and/or associated caches and servers) configured to store the one or more instructions 524.

The term “machine readable medium” may include any medium that is capable of storing, encoding, or carrying instructions for execution by the machine 500 and that cause the machine 500 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); Solid State Drives (SSD); and CD-ROM and DVD-ROM disks. In some examples, machine readable media may include non-transitory machine-readable media. In some examples, machine readable media may include machine readable media that is not a transitory propagating signal.

The instructions 524 may further be transmitted or received over a communications network 526 using a transmission medium via the network interface device 520. The Machine 500 may communicate with one or more other machines utilizing any one of a number of transfer protocols (e.g., frame relay, internet protocol (IP), transmission control protocol (TCP), user datagram protocol (UDP), hypertext transfer protocol (HTTP), etc.). Example communication networks may include wired and wireless communications, such as Ethernet, Bluetooth, Bluetooth Low Energy, other Personal Area Networks (PANs), LoRa, NFC, Wi-Fi, WiMAX, 3G, 4G, LTE, 5G, the unlicensed 915 MHz Industrial, Scientific, and Medical (ISM) frequency band, Zigbee, among others. Some standards may support mesh networks. The networks include, but are not limited to, a local area network (LAN), a low-power wide-area network (LPWAN), a wide area network (WAN), a packet data network (e.g., the Internet), mobile telephone networks (e.g., cellular networks), Plain Old Telephone (POTS) networks, and wireless data networks, e.g., Institute of Electrical and Electronics Engineers (IEEE) 802.11 family of standards known as Wi-Fi®, IEEE 802.16 family of standards known as WiMax®, NFC, IEEE 802.15.4 family of standards, a Long Term Evolution (LTE) family of standards, a Universal Mobile Telecommunications System (UMTS) family of standards, peer-to-peer (P2P) networks, among others. The NFC circuitry may be embodied as relatively short-range, high frequency wireless communication circuitry and may implement standards such as ECMA-340/ISO/IEC 18092 and/or ECMA-352/ISO/IEC 21481 to communicate with other devices. In an example, the network interface device 520 may include one or more physical jacks (e.g., Ethernet, coaxial, or phone jacks) or one or more antennas to connect to the communications network 526. In an example, the network interface device 520 may include a plurality of antennas to wirelessly communicate using at least one of single-input multiple-output (SIMO), multiple-input multiple-output (MIMO), or multiple-input single-output (MISO) techniques. In some examples, the network interface device 520 may wirelessly communicate using Multiple User MIMO techniques.

### OTHER NOTES AND EXAMPLES

Example 1 is a pest detection device including a capacitive sensor configured to detect a presence of one or more pests, one or more secondary sensors configured to detect one or more prescribed conditions either inside or outside a housing of the device, and a controller connected to the capacitive sensor and the one or more secondary sensors, the controller configured to initiate calibration of the capacitive sensor based at least in part on one or more signals received from the one or more secondary sensors.

In Example 2, the subject matter of Example 1 optionally includes wherein at least one of the one or more secondary sensors includes a mechanical sensor or switch.

In Example 3, the subject matter of Example 1 optionally includes wherein at least one of the one or more secondary sensors includes an infrared sensor.

In Example 4, the subject matter of Example 1 optionally includes wherein at least one of the one or more secondary sensors includes an environmental sensor.

In Example 5, the subject matter of Example 4 optionally includes wherein the environmental sensor includes a temperature sensor.

In Example 6, the subject matter of Example 4 optionally includes wherein the environmental sensor includes a moisture detector.

In Example 7, the subject matter of Example 1 optionally includes wherein at least one of the one or more secondary sensors includes a watchdog timer.

In Example 8, the subject matter of Example 1 optionally includes wherein the one or more secondary sensors include a plurality of secondary sensors.

In Example 9, the subject matter of Example 8 optionally includes wherein the plurality of secondary sensors are of a same sensor type.

In Example 10, the subject matter of Example 1 optionally includes wherein the plurality of secondary sensors include multiple sensor types.

In Example 11, the subject matter of Example 1 optionally further includes a battery configured to be used for calibration of the capacitive sensor.

In Example 12, the subject matter of Example 1 optionally includes wherein the controller is configured to detect capacitance changes using the capacitive sensor.

In Example 13, the subject matter of Example 1 optionally includes wherein the controller includes a microprocessor.

In Example 14, the subject matter of Example 1 optionally includes wherein the controller includes a microcontroller.

Example 15 is a method including detecting, using a capacitive sensor, a presence of one or more pests, detecting, using one or more secondary sensors, one or more prescribed conditions, and initiating, using a controller connected to the capacitive sensor and the one or more secondary sensors, calibration of the capacitive sensor based at least in part on one or more signals received from the one or more secondary sensors.

In Example 16, the subject matter of Example 15 optionally further includes disposing the capacitive sensor in a housing for a pest detection device.

In Example 17, the subject matter of Example 16 optionally further includes disposing the controller in the housing.

In Example 18, the subject matter of Example 16 optionally further includes disposing at least one of the one or more secondary sensors in the housing.

In Example 19, the subject matter of Example 16 optionally further includes disposing at least one of the one or more secondary sensors external to the housing.

In Example 20, the subject matter of Example 15 optionally includes wherein the capacitive sensor includes a plurality of independent capacitive sensors.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

The foregoing examples are not intended to be an exhaustive or exclusive list of examples and variations of the present subject matter. The above description is intended to be illustrative, and not restrictive. Those of skill in the art will appreciate additional variations of the embodiments that can be used within the scope of the teachings set forth herein. The scope of the invention should be determined with reference to the appended claims, along with the full scope of equivalents to which such claims are entitled.

What is claimed is:

1. A pest detection device, comprising:
a capacitive sensor configured to detect a presence of one or more pests within a housing;
one or more secondary sensors configured to detect one or more prescribed conditions; and
a controller connected to the capacitive sensor and the one or more secondary sensors, the controller configured to initiate calibration of the capacitive sensor based at least in part on one or more signals received from the one or more secondary sensors.

2. The pest detection device of claim 1, wherein at least one of the one or more secondary sensors includes a mechanical sensor or switch.

3. The pest detection device of claim 1, wherein at least one of the one or more secondary sensors includes an infrared sensor.

4. The pest detection device of claim 1, wherein at least one of the one or more secondary sensors includes an environmental sensor.

5. The pest detection device of claim 4, wherein the environmental sensor includes a temperature sensor.

6. The pest detection device of claim 4, wherein the environmental sensor includes a moisture detector.

7. The pest detection device of claim 1, wherein at least one of the one or more secondary sensors includes a watchdog timer.

8. The pest detection device of claim 1, wherein the one or more secondary sensors include a plurality of secondary sensors.

9. The pest detection device of claim 8, wherein the plurality of secondary sensors are of a same sensor type.

10. The pest detection device of claim 8, wherein the plurality of secondary sensors include multiple sensor types.

11. The pest detection device of claim 1, further comprising a battery configured to be used for calibration of the capacitive sensor.

12. The pest detection device of claim 1, wherein the controller is configured to detect capacitance changes using the capacitive sensor.

13. The pest detection device of claim 1, wherein the controller includes a microprocessor.

14. The pest detection device of claim 1, wherein the controller includes a microcontroller.

15. A method, comprising:
detecting, using a capacitive sensor, a presence of one or more pests within a housing;
detecting, using one or more secondary sensors, one or more prescribed conditions; and
initiating, using a controller connected to the capacitive sensor and the one or more secondary sensors, calibration of the capacitive sensor based at least in part on one or more signals received from the one or more secondary sensors.

16. The method of claim 15, further comprising disposing the capacitive sensor in a housing for a pest detection device.

17. The method of claim 16, further comprising disposing the controller in the housing.

18. The method of claim 16, further comprising disposing at least one of the one or more secondary sensors in the housing.

19. The method of claim 16, further comprising disposing at least one of the one or more secondary sensors external to the housing.

20. The method of claim 15, wherein the capacitive sensor includes a plurality of independent capacitive sensors.
